(19) United States
(12) Patent Application Publication
(10) Pub. No.: US 2020/0077164 A1
(43) Pub. Date: Mar. 5, 2020

(54) HVAC installation procedure for a telecommunications site

(71) Applicant: ETAK Systems, LLC, Huntersville, NC (US)

(72) Inventors: Anthony Gentile, Milford, PA (US); Joseph Hummer, Nashua, NH (US); Lee Priest, Charlotte, NC (US)

(21) Appl. No.: 16/120,734

(22) Filed: Sep. 4, 2018

(51) Int. Cl. H04Q 1/02; H05K 7/20

(52) U.S. Cl. CPC H04Q 1/035; H05K 7/2029

(57) ABSTRACT

A method of Heating, Ventilation, and Air Conditioning (HVAC) installation for a telecommunications site includes performing preparation to install a new HVAC unit to replace multiple existing HVAC units at the telecommunications site; installing an exhaust louver at a shelter of the telecommunications site; installing the new HVAC unit at the shelter, wherein the new HVAC unit is on an opposing wall as the exhaust louver such that airflow is enabled through an interior of the shelter; configuring the new HVAC unit, an associated controller, and one or more temperature sensors; testing the new HVAC unit ensuring operation through all programming cycles and free of alarms; and removing the multiple existing HVAC units.

### FIELD OF THE DISCLOSURE

The present disclosure generally relates to telecommunication site installation systems and methods. More particularly, the present disclosure relates to a Heating, Ventilation, and Air Conditioning (HVAC) installation procedure for a telecommunications site.

### BACKGROUND OF THE DISCLOSURE

Telecommunications providers, network operators, service providers, etc. operate networks which include various telecommunications sites. Examples of telecommunication sites include Central Offices (COs), data centers, cell sites, shelters, huts, etc. The associated networks, e.g., optical, packet, wireless, wireline, etc., are formed by associated equipment operating in the telecommunication sites. For example, due to the geographic coverage nature of wireless service, there are hundreds of thousands of cell towers in the United States. With over 200,000 cell sites in the U.S., geographically distributed everywhere, installation and maintenance at cell sites can be expensive, time-consuming, and complex. For example, cell sites include a shelter or cabinet located proximate to the cell tower. One key limiting issue in network operation is the amount of heat generated by the network equipment. As such, HVAC installation and operation is critical. Given the vast number of telecommunication sites, there is a need for efficient HVAC installation procedures.

### BRIEF SUMMARY OF THE DISCLOSURE

In an embodiment, a method of Heating, Ventilation, and Air Conditioning (HVAC) installation for a telecommunications site includes performing preparation to install a new HVAC unit to replace multiple existing HVAC units at the telecommunications site; installing an exhaust louver at a shelter of the telecommunications site; installing the new HVAC unit at the shelter, wherein the new HVAC unit is on an opposing wall as the exhaust louver such that airflow is enabled through an interior of the shelter; configuring the new HVAC unit, an associated controller, and one or more temperature sensors; testing the new HVAC unit ensuring operation through all programming cycles and free of alarms; and removing the multiple existing HVAC units.

The exhaust louver can be installed in a door. The method can further include sealing one or more openings associated with the multiple existing HVAC units. The method can further include installing the associated controller at a location in the shelter and the one or more temperature at various locations in the shelter. The method can further include installing one or more air curtains in the interior of the shelter to direct the airflow. The new HVAC unit can be installed in an area where sunlight exposure is minimized.

In another embodiment, a shelter at a telecommunications site includes equipment located in an interior of the shelter; a door providing access to the interior; and multiple existing Heating, Ventilation, and Air Conditioning (HVAC) units in the interior, wherein preparation is performed to install a new HVAC unit to replace the multiple existing HVAC units at the telecommunications site, wherein an exhaust louver is installed at the shelter, wherein the new HVAC unit is installed at the shelter, wherein the new HVAC unit is on an opposing wall as the exhaust louver such that airflow is enabled through an interior of the shelter, wherein the new HVAC unit, an associated controller, and one or more temperature sensors are configured and tested ensuring operation through all programming cycles and free of alarms, and wherein the multiple existing HVAC units are removed.

The exhaust louver can be installed in a door. One or more openings associated with the multiple existing HVAC units can be sealed. The associated controller can be installed at a location in the shelter and the one or more temperature are installed at various locations in the shelter. One or more air curtains can be installed in the interior of the shelter to direct the airflow. The new HVAC unit can be installed in an area where sunlight exposure is minimized.

### BRIEF DESCRIPTION OF THE DRAWINGS

The present disclosure is illustrated and described herein with reference to the various drawings, in which like reference numbers are used to denote like system components/method steps, as appropriate, and in which:

FIG. 1 is a diagram of an example cell site;

FIG. 2 is a diagram of an example interior of a shelter at the cell site;

FIG. 3 is a flowchart of a Method of Procedure (MOP) for installation of a new HVAC unit in the shelter;

FIG. 4 is a floorplan diagram of an example shelter; and

FIG. 5 is a flowchart of a Method of Procedure (MOP) for installation of a new HVAC unit in the shelter.

### DETAILED DESCRIPTION OF THE DISCLOSURE

In various embodiments, the present disclosure relates to a magnetic track system for transporting batteries at telecommunication sites. The magnetic track system efficiently enables transport of batteries to/from a cabinet, shelter, etc. Also, in various embodiments, the present disclosure relates to battery security systems and methods for telecommunication sites, such as cell sites. Specifically, the battery security systems and methods include a reinforced battery retention bracket for securing batteries in a telecommunication site, such as a cell site and associated shelter. An objective of the battery security systems and methods is to deter/prevent battery theft.

### Example Cell Site

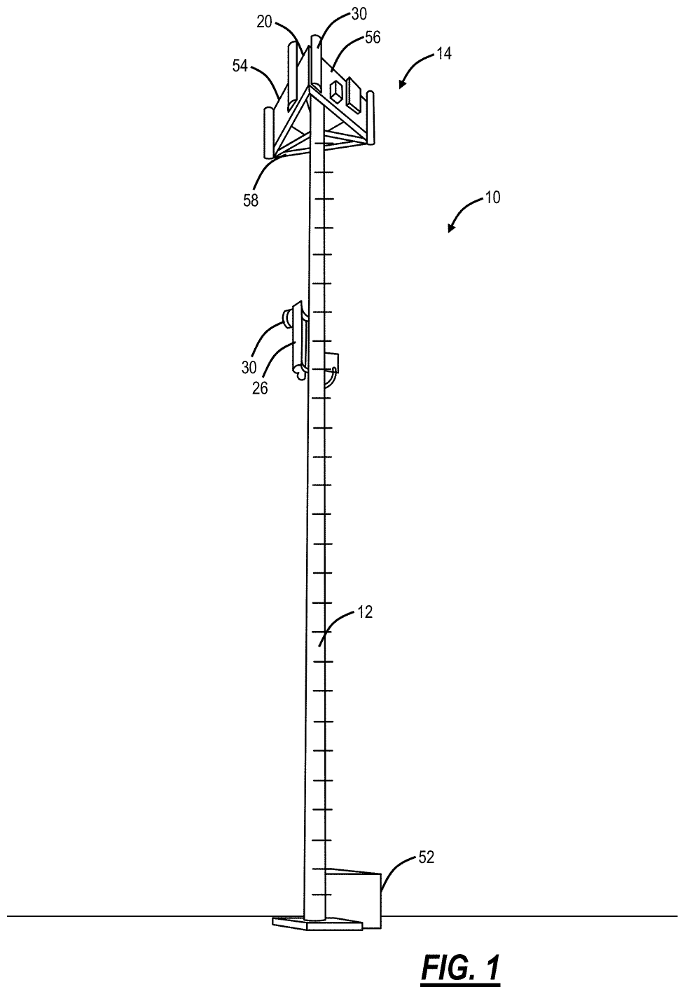

FIG. 1 is a diagram of a side view of an example cell site 10. The cell site 10 includes a cell tower 12. The cell tower 12 can be any type of elevated structure, such as 100-200 feet/30-60 meters tall. Generally, the cell tower 12 is an elevated structure for holding cell site components 14. The cell tower 12 may also include a lighting rod, a warning light, etc. Of course, there may various additional components associated with the cell tower 12 and the cell site 10 which are omitted for illustration purposes. In this embodiment, there are four sets 20, 26 of cell site components 14, such as for four different wireless service providers. In this example, the sets 20 include various antennas 30 for cellular service. The sets 20 are deployed in sectors, e.g., there can be three sectors for the cell site components—alpha, beta, and gamma. The antennas 30 are used to both transmit a radio signal to a mobile device and receive the signal from the mobile device. The antennas 30 are usually deployed as a single, groups of two, three or even four per sector. The higher the frequency of spectrum supported by the antenna 30, the shorter the antenna 30. For example, the antennas 30 may operate around 850 MHz, 1.9 GHz, and the like. The set 26 includes a microwave dish 32 which can be used to provide other types of wireless connectivity, besides cellular service. There may be other embodiments where the cell tower 12 is omitted and replaced with other types of elevated structures such as roofs, water tanks, etc.

To support the various cell site components and their operation thereof, the cell site 10 includes a shelter 50 (which can also be referred to as a cabinet, house, etc.) which include electronics and other networking equipment to support the functionality and operation. The shelter 50 can include a battery system which supports power for the various equipment at the cell site 10 when a primary power source is unavailable. The present disclosure relates to an apparatus and method for improving installation efficiency of individual batteries in the battery system. The apparatus and method are illustrated herein referencing the cell site 10 and the shelter 50, but those of ordinary skill in the art will recognize other applications are also contemplated in the telecom and data communications space.

### Example Shelter

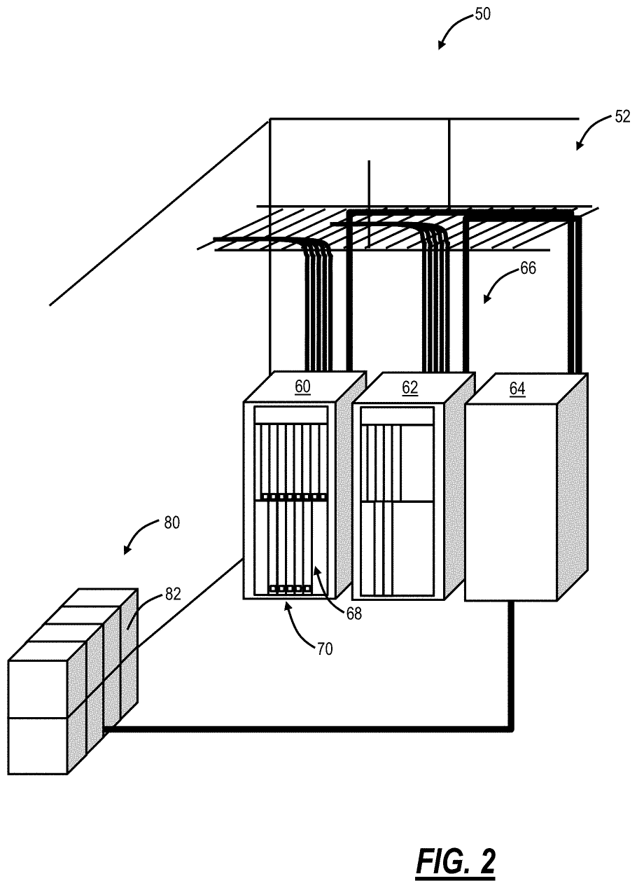

FIG. 2 is a diagram of an interior 52 of a shelter 50 at the cell site 10. Generally, the shelter 50 houses equipment associated with the cell site 10 such as wireless RF terminals 60 (e.g., LTE terminals), wireless backhaul equipment 62, power distribution 64, and the like. Generally, wireless RF terminals 60 connect to the cell site components 14 for providing associated wireless service. The wireless backhaul equipment 62 includes networking equipment to bring the associated wireless service signals to a wireline network, such as via fiber optics or the like. The power distribution 64 provides power for all of the equipment such as from the grid as well as a battery backup to enable operation in the event of power failures. Of course, additional equipment and functionality are contemplated in the interior 52. The terminals 60, equipment 62, and the power distribution 64 can be realized as rack or frame mounted hardware with cabling 66 and with associated modules 68. The modules 68 can be pluggable modules which are selectively inserted in the hardware and each can include unique identifiers 70 such as barcodes, Quick Response (QR) codes, RF Identification (RFID), physical labeling, color coding, or the like. Each module 918 can be unique with a serial number, part number, and/or functional identifier. The modules 68 are configured as needed to provide the associated functionality of the cell site.

The power distribution 64 can receive power from a primary source which is typically a local power provider. To support resiliency and redundancy when the primary source is unavailable, e.g., during a power outage, the shelter 50 can include a battery system 80 which can also be coupled to the power distribution 64. The present disclosure relates to an apparatus which is maneuverable in the shelter 50 to remove/install batteries in the battery system 80.

### HVAC MOP

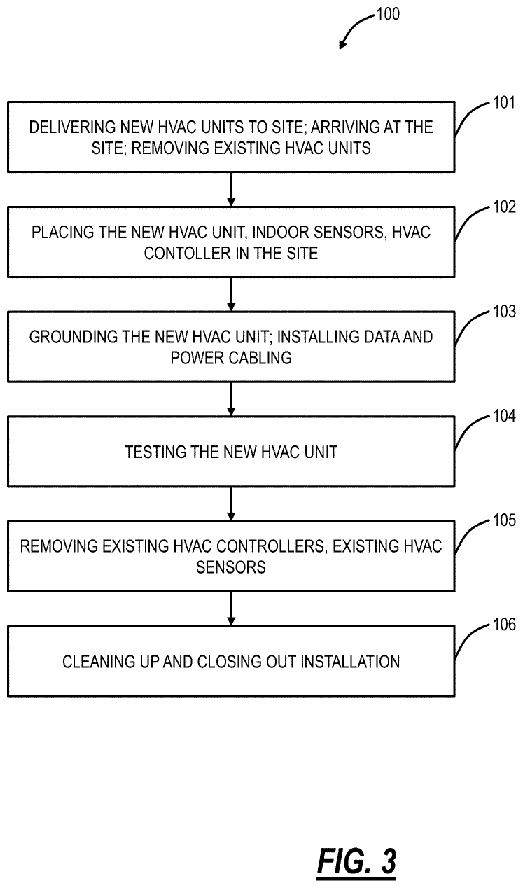

FIG. 3 is a flowchart of a Method of Procedure (MOP) 100 for installation of a new HVAC unit in the shelter 50. The MOP 100 includes preparation including delivering new HVAC units to a site 10, arriving at the site 10, and removing existing HVAC units (step 101). Additionally, the preparation can include verification the site 10 can support the new HVAC units. Note, the HVAC units can be two or more units. In an embodiment, the HVAC units can be two wall mounted units, and the existing HVAC units can be three or more which are removed for End of Life (EOL) replacement or upgrade. The removed existing HVAC units can leave openings in the shelter 50 which need to be sealed and secured.

Next, the MOP 100 includes placing the new HVAC units, indoor sensors, and HVAC controller in the shelter 50 at the site 10 (step 102). The new HVAC units can also be wall mounted and are grounded using a #2 solid down conductor that is cad-welded to a buried ring at the site 10. The indoor sensors are place around the shelter 50 to monitor temperature. The HVAC controller can be a smart controller, thermostat, control panel, etc.

The MOP 100 includes grounding the new HVAC units, and installing data and power cabling (step 103). For example, the HVAC controller can be wired to an alarm block in the shelter 50 so that HVAC alarms and warnings can be relayed to network operations. Also, the indoor sensors can be wired to the HVAC controller. The data and power cabling (wiring) can be in proper conduits in the shelter 50. These can include compression fittings with the conduit when running cables along a wall in the shelter 50. Separate conduits are used for AC and DC power. Also, wall openings can be resized as needed to accommodate the supply/returns for the new HVAC units. The use of curbs or other transitions to adapt to existing supply/return openings is avoided. Existing curbs or other adapters shall be removed/no longer necessary when new units are placed.

Once installed, the new HVAC units are tested (step 104). The testing assure the new HVAC units have the most current software, operate through all programming cycles, are free of alarms, etc. The MOP 100 can include removing existing HVAC controllers and existing HVAC sensors (step 105). This includes physical removal, de-installation, de-wiring, etc. The MOP 100 can include removing/closing off and sealing any openings existing/legacy Ancillary Fan Systems or Emergency ventilation. The MOP 100 can include checking the shelter 50 to ensure there are no gaps or crevices in the physical structure for air leakage. Finally, the MOP 100 includes cleaning up and closing out installation (step 106).

### Improved HVAC MOP

With the MOP 100, two units are installed with one being a general HVAC unit and the second being a blower which has a louver system on an opposite wall that allows for air from the blower to exit the shelter 50. The key is to install the blower and louver system in a configuration that allows for maximum air flow across the cell site equipment, namely the terminals 60, the equipment 62, and the power distribution 64.

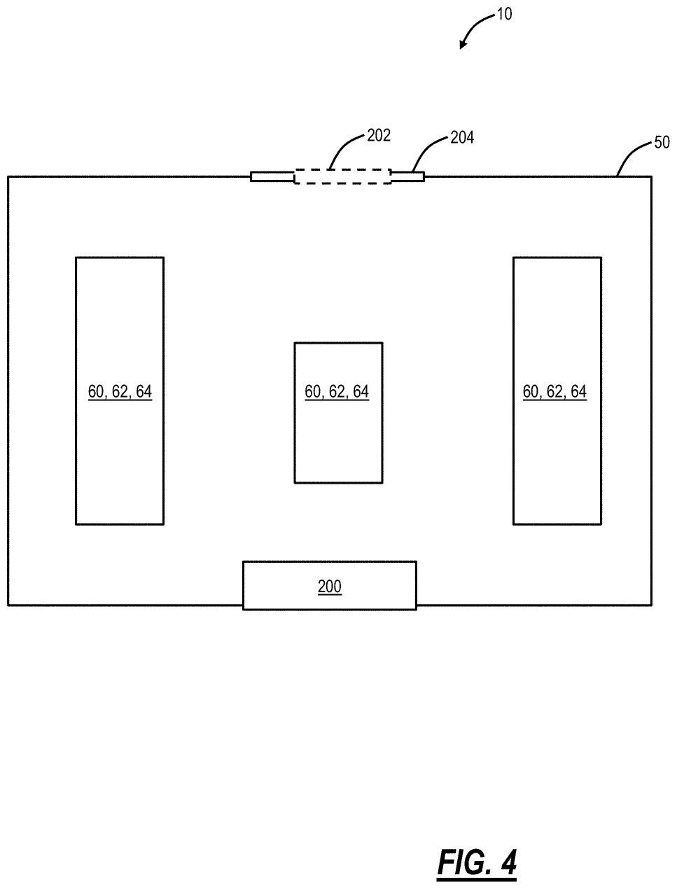

FIG. 4 is a floorplan diagram of an example shelter 50. To reduce hardware cost, installation time, and power requirements, the present disclosure includes an improved HVAC system for the shelter 50 that includes a single HVAC unit 200 instead of a two HVAC units as described in the MOP 100. The single HVAC unit 200 opposes ventilation 202 such as in a door 204 to the shelter 50. The objective here is to have one physical unit—the HVAC unit 200—and the opposing wall/location having the ventilation 202, providing adequate airflow in the shelter 50 with reduced cost, space, power, etc.

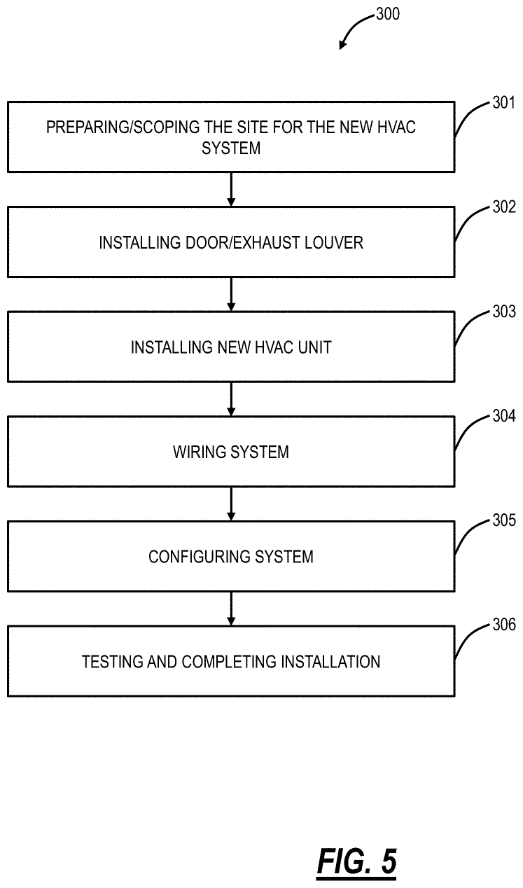

FIG. 5 is a flowchart of a Method of Procedure (MOP) 300 for installation of a new HVAC unit 200 in the shelter 50. The MOP 300 includes preparing/scoping the site 50 for the new HVAC system (step 301). The site preparing/scoping can include determining door 204 width to determine/ensure fit of an exhaust hood for the ventilation 202 on the door 204, clearance for the exhaust hood and the door stop/catch, etc. The site preparing/scoping can also include identifying grounding as well as possible alternative locations for the ventilation 202 if impractical on the door 204.

The site preparing/scoping can include determining a location of the HVAC unit 200 such as for wall mounting. This can include a location of the existing HVAC unit, to utilize one of the existing supply/return penetrations. Preferably, the location (on the exterior) is shaded to keep sunshine off of the unit, theoretically supplying relatively cooler air to the shelter 50. Also, the preferable location is off the ground—height from ground to prevent potential flood/water damage.

The site preparing/scoping can include determining a location of the exhaust louvre. Preferably, the exhaust louvre (ventilation 202) is installed in the shelter door 204 and as high up as possible (hot air rises, goal is removing as much heated air as possible—replacing with ambient air). Also, the exhaust area needs to be free from obstruction—to allow for air flow. Also, the physical dimensions for the door opening should be addressed so that the door stop/catch prevents hood from striking the shelter wall. Alternatively, the exhaust louvre (ventilation 202) could be installed in other locations besides the door 204, such as in existing cable port knock-outs or in new penetration in shelter walls.

The site preparing/scoping can include determining a location of temperature sensors, such as to identify optimum locations—relative average temperature of the room (not the coolest spot, and not next to a heat source). The site preparing/scoping can include determining a location of the HVAC controller. Finally, the site preparing/scoping can include determining airflow inside the shelter 50, such as the direction/alignment of adjustable vents; equipment locations in room, obstructions; the possible use of air curtains to direct airflow; etc.

Next, the MOP 300 includes installing the door/exhaust louver (step 302). As needed/identified in site scoping, the door stop/catch is installed to prevent damage caused from the exhaust hood striking the shelter 50. Preferably, a circular power saw with diablo (or equivalent) saw blade is used to cut out the opening for the door/exhaust louver and the cut edges are sanded to smooth for installation of louvres. Any door signage is removed if required after the louver/exhaust hood is installed on the door 204. The recommendation is to utilize flame retardant material to prevent sparks, dust, and debris from damaging equipment during the door cut procedure. Also, the recommendation is to utilize “greenfield”—metallic, flexible conduit from wall to louver control input—to eliminate need for junction box at louver control input.

Next, the MOP 300 includes installing the new HVAC unit 200 (step 303). The insulation panel is installed in the in outside part of the return opening to close gap/insulate between HVAC unit 200 and the interior shelter wall. The drip-guard is installed above the Wall-mount (HVAC manufacturers have specifications for drip guard fabrication.) Optional, good practice includes redundant weather proofing. The ground return block-off panel (interior shelter wall) is installed with through-bolts prior to mounting panel to wall, installing conduit, etc.

Next, the MOP 300 includes system wiring (step 304). The system wiring includes wiring all components as well as providing a communication wire between the HVAC unit 200 and the door unit. Also, the controller and junction boxes are cleaned for extraneous metal shavings (prevent electrical shorts).

Finally, the HVAC system is configured (step 305) and tested prior to completing the installation (step 306). Of note, the HVAC system herein expects the shelter 50 will be hotter than the typical configuration with multiple HVAC units, but this is acceptable. The sensors should be set to provide alarms if temperatures reach, e.g., 98 degrees.

Although the present disclosure has been illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following claims.

What is claimed is:

1. A method of Heating, Ventilation, and Air Conditioning (HVAC) installation for a telecommunications site, comprising:
performing preparation to install a new HVAC unit to replace multiple existing HVAC units at the telecommunications site;
installing an exhaust louver at a shelter of the telecommunications site;
installing the new HVAC unit at the shelter, wherein the new HVAC unit is on an opposing wall as the exhaust louver such that airflow is enabled through an interior of the shelter;
configuring the new HVAC unit, an associated controller, and one or more temperature sensors;
testing the new HVAC unit ensuring operation through all programming cycles and free of alarms; and
removing the multiple existing HVAC units.

2. The method of claim 1, wherein the exhaust louver is installed in a door.

3. The method of claim 1, further comprising:
sealing one or more openings associated with the multiple existing HVAC units.

4. The method of claim 1, further comprising:
installing the associated controller at a location in the shelter and the one or more temperature at various locations in the shelter.

5. The method of claim 1, further comprising:
installing one or more air curtains in the interior of the shelter to direct the airflow.

6. The method of claim 1, wherein the new HVAC unit is installed in an area where sunlight exposure is minimized.

7. A shelter at a telecommunications site comprising:
equipment located in an interior of the shelter;
a door providing access to the interior; and
multiple existing Heating, Ventilation, and Air Conditioning (HVAC) units in the interior,
wherein preparation is performed to install a new HVAC unit to replace the multiple existing HVAC units at the telecommunications site,
wherein an exhaust louver is installed at the shelter,
wherein the new HVAC unit is installed at the shelter, wherein the new HVAC unit is on an opposing wall as the exhaust louver such that airflow is enabled through an interior of the shelter,
wherein the new HVAC unit, an associated controller, and one or more temperature sensors are configured and tested ensuring operation through all programming cycles and free of alarms, and
wherein the multiple existing HVAC units are removed.

8. The shelter of claim 7, wherein the exhaust louver is installed in a door.

9. The shelter of claim 7, wherein one or more openings associated with the multiple existing HVAC units are sealed.

10. The shelter of claim 7, wherein the associated controller is installed at a location in the shelter and the one or more temperature are installed at various locations in the shelter.

11. The shelter of claim 7, wherein one or more air curtains are installed in the interior of the shelter to direct the airflow.

12. The shelter of claim 7, wherein the new HVAC unit is installed in an area where sunlight exposure is minimized.
